(19) United States
(12) Patent Application Publication
(10) Pub. No.: US 2012/0261167 A1
(43) Pub. Date: Oct. 18, 2012

(54) Transparent Electrodes, Electrode Devices, and Associated Methods

(76) Inventor: Chien-Min Sung, New Taipei City (TW)

(21) Appl. No.: 13/424,230

(22) Filed: Mar. 19, 2012

(30) Foreign Application Priority Data
Mar. 17, 2011 (TW) 100109153

(51) Int. Cl. H05K 1/09; B32B 37/02; B05D 3/00; H05K 1/03; B05D 5/12; H05K 1/02; B82Y 15/00; B82Y 40/00; B82Y 99/00; B82Y 20/00

(52) U.S. Cl. 174/254; 427/122; 156/241; 427/598; 174/257; 174/255; 977/842; 977/936; 977/950; 977/952; 977/932; 977/953

(57) ABSTRACT

Transparent electrodes, devices incorporating such electrodes, and associated methods are provided. In one aspect, for example, a method for fabricating a transparent electrode can include providing a carbon-insoluble support substrate, forming a carbon-soluble layer on the support substrate, and applying a carbon source to the carbon-soluble layer to form a plurality of graphene layers on the carbon-soluble layer. In another aspect, the method can further include providing a transparent substrate having an adhesive surface, applying the adhesive surface to the plurality of graphene layers such that the transparent substrate is adhered thereto, and removing the carbon-soluble layer and the support substrate from the plurality of graphene layers.

### PRIORITY DATA

This application claims the benefit of Taiwan Patent Application Serial No. 100109153, filed on Mar. 17, 2011, which is incorporated herein by reference.

### BACKGROUND OF THE INVENTION

Generally, transparent electrodes are necessary components used in LCD-TVs and cameras' displays. ITO (indium tin oxide) is frequently used for providing transparent electrodes, however ITO is a type of ceramic material that is fragile, which may be unsuitable for fabricating certain transparent electrodes. Other materials such as tin may also be used for manufacturing transparent electrodes, but the cost is high since the raw material can be expensive.

### SUMMARY OF THE INVENTION

The present disclosure provides transparent electrodes, devices incorporating such electrodes, and associated methods. In one aspect, for example, a method for fabricating a transparent electrode can include providing a carbon-insoluble support substrate, forming a carbon-soluble layer on the support substrate, and applying a carbon source to the carbon-soluble layer to form a plurality of graphene layers on the carbon-soluble layer. The thickness of the plurality of graphene layers can be controlled by the carbon-soluble layer, and the carbon source can be provided by a carbon-containing gas for controlling the growing speed of the plural graphene layers. In another aspect, the method can further include providing a transparent substrate having an adhesive surface, applying the adhesive surface to the plurality of graphene layers such that the transparent substrate is adhered thereto, and removing the carbon-soluble layer and the support substrate from the plurality of graphene layers. In another aspect, the transparent substrate is a flexible transparent substrate. Non-limiting examples of transparent substrates can include a glass substrate, a PET substrate, or the like.

The carbon-soluble layer can be removed by any technique that allows such a removal without significant damage to the graphene layers. Non-limiting examples can include physically pulling the carbon-soluble layer off the plurality of graphene layers, acid etching, laser etching, and the like.

In one aspect, the carbon source is a carbon-containing gas that is discretely applied to the carbon-soluble layer. In another aspect, applying the carbon source to the carbon-soluble layer further includes applying a reactive gas to the carbon-soluble layer. Non-limiting examples of reactive gasses include hydrogen, oxygen, tetrafluoromethane, and the like, including a combination thereof.

In yet another aspect, the method can include doping a dopant into the plurality of graphene layers. Non-limiting examples of dopants can include lithium, beryllium, boron, fluorine, nitrogen, oxygen, aluminum, silicon, phosphorus, sulfur, chlorine, and the like, including combinations thereof. In a further aspect, the plurality of graphene layers are doped to a concentration of about 1 at % or less based on the total number of atoms in the plurality of graphene layers. In yet a further aspect, the method can include providing an external magnetic field to the carbon-soluble layer to modify a crystal lattice orientation of the plurality of graphene layers.

Various support substrate materials are contemplated, and any material capable of receiving a carbon-soluble layer is considered to be within the present scope. Non-limiting examples can include copper, silicon, sapphire, silicon oxide, silicon dioxide, quartz, glass, and the like, including combinations thereof.

In one aspect, the carbon-soluble layer is a metal. Non-limiting examples of useful metals can include nickel, cobalt, iron, palladium, platinum, and the like, including alloys thereof. In another aspect, the carbon-soluble layer can have a thickness of from about 1 nm to about 1 μm.

The carbon source can include any source of carbon that can be utilized to form graphene materials. The carbon source can be a carbon-containing gas or a non-gas material such as graphite. Non-limiting examples include methane, acetylene, graphite, and the like, including a combination thereof. In another aspect, applying the carbon source to the carbon-soluble layer to form the plurality of graphene layers further includes heating the carbon-soluble layer to a temperature of from about 400° C. to about 1000° C.

The present disclosure additionally provides transparent electrode devices. In one aspect, for example, such a device can include a transparent substrate and a plurality of graphene layers coupled to the transparent substrate by an adhesive layer. In one aspect, the plurality of graphene layers has a light-transparency of at least 80%. In another aspect, the plurality of graphene layers has an electrical conductivity at least 10⁻³ s/cm. In a further aspect, the plurality of graphene layers includes from about 10 to about 500 graphene layers.

The present disclosure additionally provides electronic devices including a transparent electrode. Non-limiting examples of such devices can include a light-emitting diode (LED), a liquid crystal device (LCD), an organic light-emitting diode (OLED), a thin film transistor (TFT), a solar cell, and the like. Such a device can also include a semiconductor element. Non-limiting examples of such semiconductor elements can include an integrated circuit, a radio frequency identification devices (RFID) circuit, a sensor, a micro electro mechanical system (MEMS), and the like.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a process flow chart for fabricating a transparent electrode according to an embodiment of the present disclosure; and

FIGS. 2A to 2E are process flow charts for fabricating a transparent electrode according to an embodiment of the present disclosure.

### DETAILED DESCRIPTION OF THE INVENTION

### Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a dopant” includes reference to one or more of such dopants, and reference to “the graphene layer” includes reference to one or more of such layers.

As used herein, “vapor deposited” refers to materials which are formed using vapor deposition techniques. “Vapor deposition” refers to a process of forming or depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, cathodic arc, and the like.

As used herein, “chemical vapor deposition,” or “CVD” refers to any method of chemically forming or depositing diamond particles in a vapor form upon a surface. Various CVD techniques are well known in the art.

As used herein, “physical vapor deposition,” or “PVD” refers to any method of physically forming or depositing diamond particles in a vapor form upon a surface. Various PVD techniques are well known in the art.

As used herein, “substrate” refers to a support surface to which various materials can be joined in forming a semiconductor or semiconductor-on-diamond device. The substrate may be any shape, thickness, or material, required in order to achieve a specific result, and includes but is not limited to metals, alloys, ceramics, and mixtures thereof. Further, in some aspects, the substrate may be an existing semiconductor device or wafer, or may be a material which is capable of being joined to a suitable device.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

### THE DISCLOSURE

The present disclosure provides methods for fabricating a transparent electrode, methods for fabricating a transparent electrode from graphene, including associated transparent electrodes having high electrical conductivity, high transparency, and high crystal quality. The present disclosure additionally provides devices incorporating such transparent electrodes.

In one aspect, for example, a method for fabricating a transparent electrode can include providing a carbon-insoluble support substrate, forming a carbon-soluble layer on the support substrate, and applying a carbon source to the carbon-soluble layer to form a plurality of graphene layers on the carbon-soluble layer. The thickness of the plurality of graphene layers can be controlled by the carbon-soluble layer, and the carbon source can be utilized for controlling the growing speed of the plural graphene layers. In another aspect, the method can further include providing a transparent substrate having an adhesive surface, applying the adhesive surface to the plurality of graphene layers such that the transparent substrate is adhered thereto, and removing the carbon-soluble layer and the support substrate from the plurality of graphene layers. In another aspect, the transparent substrate is a flexible transparent substrate. Non-limiting examples of transparent substrates can include a glass substrate, a PET (Polyethylene terephthalate) substrate, or the like.

In one aspect, the carbon source is a carbon-containing gas that is discretely applied to the carbon-soluble layer. The carbon-containing gas can be discretely provided to the carbon-soluble layer so as to control the growing speed of the plural graphene layers. The carbon source can include any source of carbon that can be utilized to form graphene materials. The carbon source can be a carbon-containing gas or a non-gas material such as graphite. Non-limiting examples include methane, acetylene, graphite, and the like, including a combination thereof. Other liquid carbon sources or solid carbon sources may also be used. For example, a graphene layer can be grown on a surface of the carbon-soluble layer after coating with a solution having acetone diluted with poly (methyl methacrylate) (PMMA) on the carbon-soluble layer by spin coating. In another aspect, applying the carbon source to the carbon-soluble layer to form the plurality of graphene layers further includes heating the carbon-soluble layer to a temperature of from about 400° C. to about 1000° C.

In another aspect, applying the carbon source to the carbon-soluble layer further includes applying a reactive gas to the carbon-soluble layer. The reactive gas can be applied to the carbon-soluble layer in order to remove by etching unstable carbon atoms located in defects of the graphene layers, and therefore increase the purity of the graphene material. Non-limiting examples of reactive gasses include hydrogen, oxygen, tetrafluoromethane, other fluoro-containing gases, and the like, including a combination thereof. The reactive gas can be heated to form plasma by heating filaments, microwaves, and the like.

In yet another aspect, the method can include doping a dopant into the plurality of graphene layers. Non-limiting examples of dopants can include lithium, beryllium, boron, fluorine, nitrogen, oxygen, aluminum, silicon, phosphorus, sulfur, chlorine, and the like, including combinations thereof. Such doping can, in one aspect, form a transparent electrode that is a semiconductive element. In a further aspect, the plurality of graphene layers are doped to a concentration of about 1 at % or less based on the total number of atoms in the plurality of graphene layers. In yet a further aspect, the method can include providing an external magnetic field to the carbon-soluble layer to modify a crystal lattice orientation of the plurality of graphene layers.

In order to achieve a desired crystal lattice orientation, increased crystal quality, and uniform crystal lattice orientations, an external magnetic field can be applied to the carbon-soluble layer during graphene formation to enable the graphene to be well aligned. In one aspect, such alignment can increase the electrical current speed in a specific direction.

The carbon-soluble layer can be removed by any technique that allows such a removal without significant damage to the graphene layers. Non-limiting examples can include physically pulling the carbon-soluble layer off the plurality of graphene layers, acid etching, laser etching, and the like. Non-limiting examples of etching acids can include sulfuric acid, hydrochloric acid, aqua regia, chloric acid, and the like. Furthermore, multiple methods of removal are also contemplated, such as physical removal of the support substrate and acid etching of the remaining carbon-soluble layer.

Various support substrate materials are contemplated, and any material capable of receiving a carbon-soluble layer is considered to be within the present scope. Non-limiting examples can include copper, silicon, sapphire, silicon oxide, silicon dioxide, quartz, glass, and the like, including combinations thereof.

The carbon-soluble layer can be any material capable of allowing the formation of graphene thereupon. In one aspect, the carbon-soluble layer is a metal. Non-limiting examples of useful metals can include nickel, cobalt, iron, palladium, platinum, and the like, including alloys thereof. In another aspect, the carbon-soluble layer can have a thickness of from about 1 nm to about 1 nm. In yet another aspect, the carbon-soluble layer can have a thickness of from about 10 nm to about 100 nm.

Various adhesive layer materials are contemplated for the attachment of the graphene layers to the transparent substrate, and any adhesive capable of such attachment is considered to be within the present scope. Non-limiting examples of such adhesive materials can include acrylic glues, epoxy, various resins, and the like. In one aspect, the adhesive material can be a double-side adhesive tape.

The present disclosure additionally provides transparent electrode devices. In one aspect, for example, such a device can include a transparent substrate and a plurality of graphene layers coupled to the transparent substrate by an adhesive layer. In one aspect, the plurality of graphene layers has a light-transparency of at least 80%. In another aspect, the plurality of graphene layers has an electrical conductivity at least 10⁻³ s/cm. In a further aspect, the plurality of graphene layers includes from about 10 to about 500 graphene layers.

The present disclosure additionally provides electronic devices including a transparent electrode. Non-limiting examples of such devices can include a light-emitting diode (LED), a liquid crystal device (LCD), an organic light-emitting diode (OLED), a thin film transistor (TFT), a solar cell, and the like. In one aspect, the device can include any device or device design that can benefit from a transparent electrode. Such a device can also include a semiconductor element. Non-limiting examples of such semiconductor elements can include an integrated circuit, a radio frequency identification devices (RFID) circuit, a sensor, a micro electro mechanical system (MEMS), and the like.

Traditional methods for forming graphene can include decomposing a carbon-containing gas at a high temperature (e.g. 1000° C.) followed by vapor deposition to precipitate a graphene layer on a surface of a metal (such as copper) from the carbon-containing gas, in which the carbon-containing gas may be a mixture of methane, hydrogen gas, and argon gas. However, due to the insolubility of the copper to the carbon, only one or two layers of graphene are obtained from the carbon-containing gas. In addition, defects can exist in such graphene layers, which substantially reduce electrical conductivity.

If a carbon-soluble metal such as nickel, cobalt, iron, palladium, or platinum is used for precipitating graphene, hundreds (even thousands) of layers of graphene can be grown due to the high carbon-solubility. The presence of the carbon-soluble metal, however, can greatly decrease the light-transparency of the material. Thus, by removing the carbon-soluble metal from the graphene, transparent electrodes can be achieved.

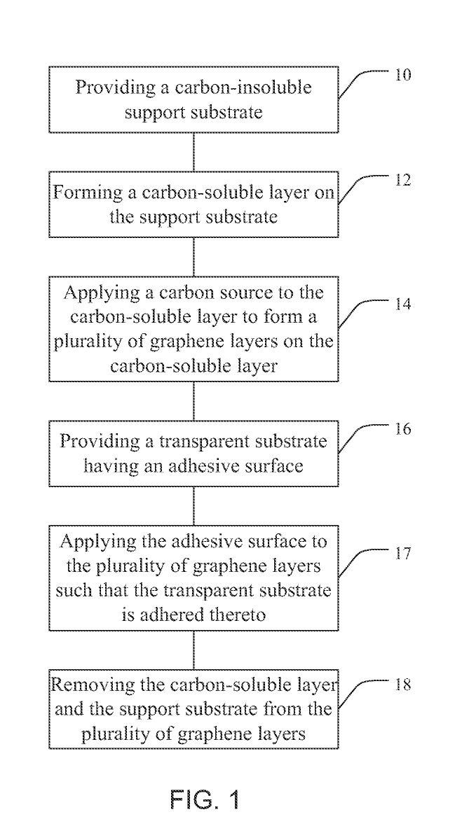

FIG. 1 shows a process flow chart for fabricating a transparent electrode of the present disclosure. Such a method can include providing a carbon-insoluble support substrate 10, forming a carbon-soluble layer on the support substrate 12, and applying a carbon source to the carbon-soluble layer to form a plurality of graphene layers on the carbon-soluble layer 14. The method can further include providing a transparent substrate having an adhesive surface 16, applying the adhesive surface to the plurality of graphene layers such that the transparent substrate is adhered thereto 17, and removing the carbon-soluble layer and the support substrate from the plurality of graphene layers 18.

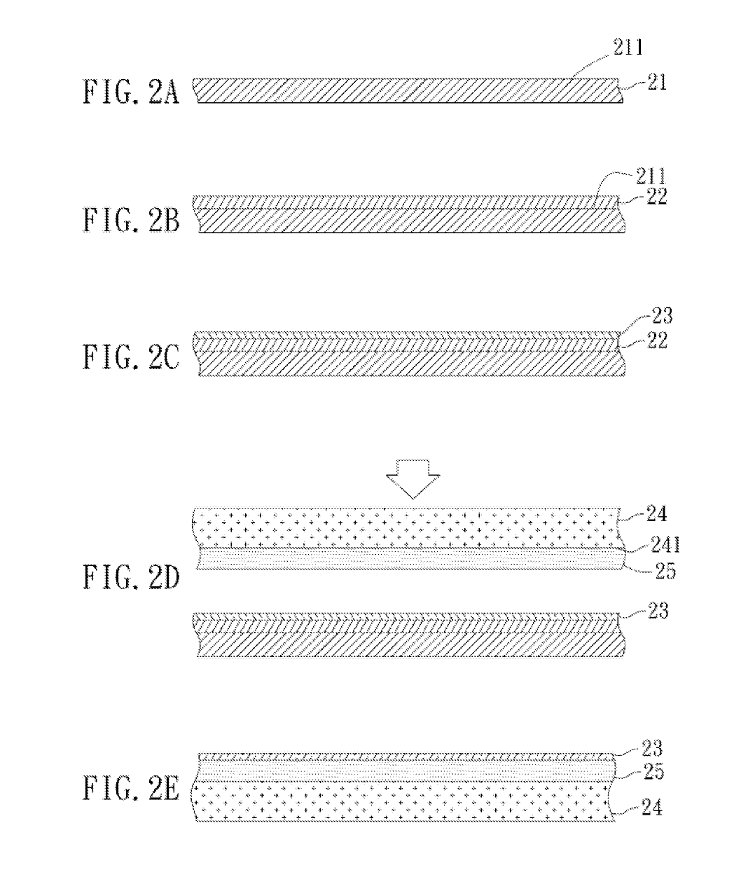

As is shown in FIG. 2, one exemplary technique for fabricating a transparent electrode can be performed as follows: with reference to FIG. 2A, a support substrate 21 is provided, which has a first surface 211. As shown in FIG. 2B, a carbon-soluble layer 22 is formed on the first surface 211 of the support substrate 21 by a suitable process such as, for example, chemical vapor deposition (CVD), evaporation deposition, sputtering coating, ion plating, or the like. A carbon source (not shown) comprising, for example, a carbon-containing gas is provided, and the carbon source is heated to form plurality of graphene layers 23 on the carbon-soluble layer 22 as is shown in FIG. 2C.

Furthermore, as shown in FIG. 2D, a transparent substrate 24 having a second surface 241 is provided, and an adhesive layer 25 is formed on the second surface 241 of the transparent substrate 24. The adhesive layer 25 is coupled to the plurality of graphene layers 23. Following coupling, the carbon-soluble layer 22 is removed from the plurality graphene layers 23 along with the support substrate 21, as is shown in FIG. 2E. This graphene transparent electrode structure includes the transparent substrate 24, the adhesive layer 25, and the plural graphene layers 23. In the present example, the carbon-containing gas can be discretely provided so as to control the growing speed of the plural graphene layers 23.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method for fabricating a transparent electrode, comprising:
providing a carbon-insoluble support substrate;
forming a carbon-soluble layer on the support substrate; and
applying a carbon source to the carbon-soluble layer to form a plurality of graphene layers on the carbon-soluble layer, wherein the thickness of the plurality of graphene layers is controlled by the carbon-soluble layer.

2. The method of claim 1, further comprising:
providing a transparent substrate having an adhesive surface;
applying the adhesive surface to the plurality of graphene layers such that the transparent substrate is adhered thereto; and
removing the carbon-soluble layer and the support substrate from the plurality of graphene layers.

3. The method of claim 2, wherein in the carbon-soluble layer is removed by pulling the carbon-soluble layer off the plurality of graphene layers or by acid-etching the carbon-soluble layer from the plurality of graphene layers

4. The method of claim 2, wherein the transparent substrate is a flexible transparent substrate.

5. The method of claim 1, wherein the carbon source is a carbon-containing gas that is discretely applied to the carbon-soluble layer.

6. The method of claim 1, wherein applying the carbon source to the carbon-soluble layer further includes applying a reactive gas to the carbon-soluble layer.

7. The method of claim 6, wherein the reactive gas is includes a member selected from the group consisting of hydrogen, oxygen, tetrafluoromethane, or a combination thereof.

8. The method of claim 1, further comprising doping a dopant into the plurality of graphene layers.

9. The method of claim 8, wherein the dopant includes a member selected from the group consisting of lithium, beryllium, boron, fluorine, nitrogen, oxygen, aluminum, silicon, phosphorus, sulfur, chlorine, and combinations thereof.

10. The method of claim 8, wherein the plurality of graphene layers are doped to a concentration of about 1 at % or less based on the total number of atoms in the plurality of graphene layers.

11. The method of claim 1, further comprising providing an external magnetic field to the carbon-soluble layer to modify a crystal lattice orientation of the plurality of graphene layers.

12. The method of claim 1, wherein the support substrate includes a member selected from the group consisting of copper, silicon, sapphire, silicon oxide, silicon dioxide, quartz, glass, or combinations thereof.

13. The method of claim 1, wherein the carbon-soluble layer is a metal.

14. The method of claim 13, wherein the metal is nickel, cobalt, iron, palladium, platinum, or an alloy thereof.

15. The method of claim 1, wherein the carbon-soluble layer has a thickness of from about 1 nm to about 1 μm.

16. The method of claim 1, wherein the carbon source is methane, acetylene, or a combination thereof.

17. The method of claim 1, wherein applying the carbon source to the carbon-soluble layer to form the plurality of graphene layers further includes heating the carbon-soluble layer to a temperature of from about 400° C. to about 1000° C.

18. The method of claim 1, wherein the carbon source is a carbon-containing gas or graphite.

19. A transparent electrode device, comprising:
a transparent substrate; and
a plurality of graphene layers coupled to the transparent substrate by an adhesive layer.

20. The device of claim 19, wherein the plurality of graphene layers has a light-transparency of at least 80%.

21. The device of claim 19, wherein plurality of graphene layers has an electrical conductivity at least 10⁻³ s/cm.

22. The device of claim 19, wherein the plurality of graphene layers includes from about 10 to about 500 graphene layers.

23. The device of claim 19, wherein the transparent substrate is a flexible transparent substrate.

24. The device of claim 19, wherein the transparent substrate includes a glass substrate or a PET substrate.

25. An electronic device including the transparent electrode of claim 19, wherein electronic device is a light-emitting diode (LED), a liquid crystal device (LCD), an organic light-emitting diode (OLED), a thin film transistor (TFT), or a solar cell.

26. A semiconductor element for an electronic device having a transparent electrode made according to claim 2.

27. The semiconductor element of claim 26, wherein the electronic device is an integrated circuit, a radio frequency identification devices (RFID) circuit, a sensor, or a micro electro mechanical system (MEMS).
